(19) United States
(12) Patent Application Publication
(10) Pub. No.: US 2023/0228829 A1
(43) Pub. Date: Jul. 20, 2023

(54) Magnetic Field Generation with Particle Enhancement with Charge-based Absorption

(71) Applicant: Robert Samuel Melodia, Rio Rancho, NM (US)

(72) Inventor: Robert Samuel Melodia, Rio Rancho, NM (US)

(73) Assignee: Robert Samuel Melodia, Rio Rancho, NM (US)

(21) Appl. No.: 17/994,390

(22) Filed: Nov. 28, 2022

Related U.S. Application Data
(60) Provisional application No. 63/285,099, filed on Dec. 2, 2021.

(51) Int. Cl. G01R 33/12; H01F 5/00; H02N 11/00

(52) U.S. Cl. CPC G01R 33/1276; H01F 5/00; H02N 11/008

(57) ABSTRACT

A generation, enhancement, and absorption system for the acquisition of energy from a predetermined chosen environment. The generation, enhancement, absorption system absorbs energy through a process whereby magnetic/electrical fields interact and interlace to create, develop, and support a platform magnetic/electrical energy field that assists and supports in the acquisition of energy from an environment to the generation, enhancement, and absorption system. Coils are used to create magnetic/electrical fields. Ions are placed with the particles in the space surrounding within and without the generation, enhancement, and absorption system. The method of interacting and interlacing of fields creates a platform magnetic/electrical field that moves in a particular direction. The platform magnetic/electrical field starts to access an environmental energy field. The platform magnetic/electrical energy field acquires energy from the environment and transfers to the Magnetic Field Generation with Particle Enhancement with Charge-based Absorption system.

### BACKGROUND OF THE INVENTION

The present invention relates in general to energy, energy absorption, and energy transfer. By a predetermined absorbing particular type of charge-based energy from a different predetermined particular type of energy state a user can increase the amount of time that a user can be using a particular machine, device, personal vehicles, commercial equipment, or anything else that runs on predetermined characteristic particular type of charge-based energy. This predetermined particular type of charge-based energy absorption, and predetermined particular type of energy transfer, will allow a decrease in the carbon footprint, a decrease in pressure on the energy grid thereby decreasing the stress on the energy system as a whole. This predetermined particular type of charge-based energy absorption and predetermined particular type of energy transfer will allow predetermined particular type of charge-based energy to be absorbed from one predetermined particular type of energy form and then transferred to another predetermined particular type of energy form. In space this device will allow greater energy diversity thereby increasing energy stability and distance of usage or travel. It will help decrease the use and dependency on many types of fossil fuels and other energy sources dangerous to the environment, space, and dangerous to people in general.

### BRIEF SUMMARY OF THE INVENTION

The following is a Brief Summary of the present invention that summarizes only one embodiment of the present invention of a Magnetic Field Generation with Particle Enhancement with Charge-based Absorption. This is a predetermined particular type of particular type of charge-based energy absorption for the conversion of one predetermined particular type of form of charge-based energy, the choice of predetermined particular type of charge-based energy or predetermined particular type of charge-based energy field, that is predetermined by the user, for example, the Particle Field in this particular embodiment, to another predetermined particular type of charge-based form of energy, for example, to AC or DC electricity, which can used for the running of anything that requires a characteristic particular type of charge-based energy to run, such as the electronics at home, a predetermined particular type of charge-based energy for propulsion for such things as electric vehicles, advanced aerospace platforms, aerospace vehicles such as jets or space vehicles of all kinds that have charge-based systems, a place of business, a place or equipment outside in the environment to augment systems already in use for a predetermined particular type of charge-based energy, in outer space, on any planetary system which could include planets, moons or the like, use for assistance in predetermined particular type of charge-based energy absorption for equipment of all kinds in multiple places, in multiple industries or anything else powered by charge-based energy.

Alternatively, a predetermined particular type of absorbefacient/conductive property, for example, may contain copper, as in this one particular embodiment of the present invention, other predetermined particular type of material that would be available that would be suitable for alternative embodiments of the subject matter of the disclosure, for examples such as aluminum or other similar particular type of materials, as desired by the user. Those in the art will understand that any particular type of suitable material, now known or hereafter developed may be used in the present embodiment described herein, for the predetermined particular type of absorption, predetermined particular type of transfer, or predetermined particular type of movement of a said predetermined particular type of charge-based energy or said predetermined particular type of charge-based energy wave. A said predetermined particular type of charge-based energy or said predetermined particular type of charge-based energy wave that is being particular type of absorbed, particular type of separated, particular type of transferred, and then moved by a particular type of internal component system comprising of a plurality of particular type of part that have a said predetermined particular type of absorbefacient/conductive property, as desired by the user. Said predetermined particular type of charged-based energy is then sent through a suitable predetermined particular type of charge-based magnetic/electrical wire, or any other particular type of medium to transfer particular type of charge-based energy, that may be circular, flat or any other shape now known or hereafter developed may be used, as desired by the user, that may have predetermined particular type of composition properties and predetermined particular type of composition characteristics, to a predetermined particular type of containment or a predetermined particular type of storage system that may be used, now known or hereafter developed for the collection or storage of particular type of charge-based energy, such as a battery or a group of batteries of any kind, capacitors, super-capacitors or ultra-capacitors, such as Maxwell Inc. or any other type of containment or storage means, as desired by the user.

Alternatively, a said Magnetic Field Generation with Particle Enhancement with Charge-based Absorption that comprises of a said particular type of internal component system further comprising of said plurality of particular type of part that have a said predetermined particular type of absorbefacient/conductive property that help to form a said predetermined Magnetic Field Generation with Particle Enhancement with Charge-based Absorption that predetermined particular type of field form around and within the predetermined particular type of coil in a predetermined particular type of configuration, a predetermined particular type of size, a predetermined particular type of direction and has predetermined particular type of absorbefacient/conductive property.

Alternatively, a particular type of coil, which is with or without a particular type of covering, for example, a predetermined particular type of bare magnetic/electrical wire is used in this particular embodiment of the present invention, is made of a said predetermined particular type of magnetic/electrical wire of a predetermined particular type of size, a predetermined particular type of shape, a predetermined particular type of length and a predetermined particular type of chemical composition, for example, copper or other material now known or hereafter developed may be used in this particular embodiment of the present invention, in a predetermined sinuous spiral configuration, in this particular embodiment of the present invention, starting with a predetermined diameter, at a predetermined starting point, opposite said end point, as desired by the user, and sinuous spiral configuration from a predetermined distance from the center of the predetermined Magnetic Field Generation with Particle Enhancement with Charge-based Absorption, in a predetermined direction, with one said wire on top of another said wire for a plurality of predetermined particular type of magnetic/electrical wire, for example, in a decreasing sinuous spiral diameter, in this particular embodiment of the present invention, that is in parallel with and perpendicular to a said predetermined Magnetic Field Generation with Particle Enhancement with Charge-based Absorption around and within for a predetermined length, to a predetermined diameter, of a predetermined size at a predetermined endpoint opposite a said predetermined starting point. At a predetermined point along length of predetermined particular type of coil there is a decreasingly sinuous spiral direction that of the predetermined starting point and starts at a predetermined point along said predetermined length of wire and revolves in a predetermined sinuous spiral direction around said predetermined point along predetermined length of predetermined wire sinuous spiral direction at a predetermined distance from predetermined sinuous spiral direction prior to predetermined sinuous spiral change in a predetermined direction at a predetermined length prior to beginning predetermined sinuous spiral revolutions in a predetermined increase in sinuous spiral diameter. A said predetermined particular type of coil carries a predetermined polarity from a predetermined outside source, such as a said predetermined particular type of storage, to a predetermined starting point and follows in a predetermined path, in a predetermined direction, for a predetermined length of predetermined particular type of magnetic/electrical wire of a said predetermined particular type of coil to a predetermined endpoint of a said predetermined outside source such as a manner of mechanical or electronic unit, for example, as in a particular type of automobile or a plurality of units, that may or may not be placed in a series, as in a particular type of electrical system of a home, business or other places where particular type of charge-based energy is stored or used.

Alternatively, a predetermined number of space, which lies both within and without a said predetermined center of particular type of coil and radially surrounds a said predetermined center of coil at a predetermined distance from said predetermined center of particular type of coil with a predetermined height, a predetermined width and a predetermined length of a said predetermined space, and on a side facing towards said predetermined center of particular type of coil and radially around a plurality of predetermined side, a plurality of predetermined edge and a plurality of predetermined surfaces of a said predetermined center of particular type of coil and through a said predetermined particular type of wire of a said predetermined particular type of coil, both parallel with and perpendicular to a said predetermined center of particular type of coil and both parallel with and perpendicular to a said predetermined center of said predetermined particular type of coil.

Alternatively, a said predetermined number of particular type of coil whereby, in this particular embodiment of the present invention, a said predetermined particular type of coil, which is bare and without a covering, in this particular embodiment of the present invention, is made of a said predetermined particular type of magnetic/electrical wire of a predetermined size, a predetermined particular type of shape, a predetermined length and a predetermined characteristic particular type of composition, for example, copper in this particular embodiment of the present invention, a predetermined sinuous spiral configuration, in this particular embodiment of the present invention, in a predetermined direction starting with a predetermined diameter, at a predetermined starting point, opposite said predetermined end point, as desired by the user, and predetermined number of sinuous spiral revolution with a said predetermined particular type of magnetic/electrical wire beside another said predetermined particular type of magnetic/electrical wire for the transfer of a predetermined particular type of charge-based energy for a plurality of predetermined particular type of magnetic/electrical wire, for example, having the form of a decreasing sinuous spiral in a predetermined configuration, in this particular embodiment of the present invention, for a predetermined length that is parallel with and perpendicular to a said predetermined Magnetic Field Generation with Particle Enhancement with Charge-based Absorption that is parallel with and perpendicular to a said predetermined number of said predetermined particular type of coil at a predetermined distance that is parallel with and perpendicular to a said predetermined particular type of charge-based platform magnetic/electrical field that is parallel with and perpendicular to a said predetermined Magnetic Field Generation with Particle Enhancement with Charge-based Absorption and a predetermined distance from a said predetermined particular type of coil following a predetermined direction in a diameter of a predetermined size in a predetermined direction in a predetermined diameter at a predetermined length of said predetermined particular type of magnetic/electrical wire, to the other predetermined endpoint opposite a said predetermined starting point. A said predetermined particular type of coil carries a predetermined polarity from a predetermined starting point, opposite said ending point, from a predetermined particular type of outside source and follows a predetermined direction of a predetermined length of said predetermined particular type of magnetic/electrical wire, traveling through said predetermined particular type of coil to a predetermined endpoint to a said predetermined outside source.

Alternatively, a predetermined space which lies facing one predetermined side of a said predetermined particular type of coil that is facing a predetermined distance from a said predetermined particular type of coil and a predetermined distance with a predetermined width, a predetermined length and a predetermined height, which surrounds a said predetermined wire of a said predetermined particular type of lower coil on a plurality of predetermined sides, on a plurality of predetermined edges and on a plurality of predetermined surfaces of a said predetermined particular type of coil and parallel with and perpendicular to a said predetermined particular type of magnetic/electrical wire of a said predetermined particular type of coil which surrounds a said predetermined particular type of magnetic/electrical wire of a said predetermined particular type of coil on a plurality of sides perpendicular to and parallel with a said predetermined particular type of magnetic/electrical wire of a said particular type of coil and sinuous spiral around on a plurality of predetermined side, on a plurality of predetermined edge and on a plurality of predetermined surface of a said predetermined particular type of coil and sinuous spiral around on a plurality of predetermined side, on a plurality of predetermined edge and on a plurality of predetermined surface of a said predetermined particular type of coil.

Alternatively, a said predetermined number of particular type of coil is placed at a predetermined starting point facing a said predetermined Magnetic Field Generation with Particle Enhancement with Charge-based Absorption and opposite facing in an opposite direction from a said predetermined Magnetic Field Generation with Particle Enhancement with Charge-based Absorption at a predetermined distance from a said predetermined Magnetic Field Generation with Particle Enhancement with Charge-based Absorption and a predetermined distance from a said predetermined particular type of Outer Housing.

Alternatively, placed in between a said plurality of said predetermined number of particular type of coil and a said predetermined Magnetic Field Generation with Particle Enhancement with Charge-based Absorption is a predetermined number of space which lies in between facing a predetermined side of a said of predetermined number of particular type of coil and a predetermined side facing a said predetermined number of particular type of coil at a predetermined distance from a said predetermined Magnetic Field Generation with Particle Enhancement with Charge-based Absorption.

Alternatively, placed in between a said plurality of said predetermined number of particular type of coil and opposite at a predetermined distance to said predetermined number of particular type of coil and a said predetermined Magnetic Field Generation with Particle Enhancement with Charge-based Absorption is a predetermined sinuous spiral configuration consisting of a plurality of predetermined sinuous spiral revolution in a predetermined particular type of Torus configuration that is at a predetermined distance from a predetermined particular type of Upper Coil, a predetermined distance from a predetermined particular type of Lower Coil, a predetermined distance from the said predetermined particular type of Outer Casing on all said predetermined number of side, a predetermined distance from the predetermined particular type of Outer Casing Lid, a predetermined distance from the bottom of predetermined particular type of Outer Casing. A said predetermined particular type of Torus lies in between facing a predetermined side of a said predetermined particular type of coil configuration and a predetermined point in space assisting in the particular type of absorption of said predetermined number of particular type of energy particle and predetermined number of particular type of particle that is facing at a predetermined distance from a said predetermined Magnetic Field Generation with Particle Enhancement with Charge-based Absorption, at a predetermined distance within a said predetermined coil configuration of predetermined width, of a predetermined length, of a predetermined height perpendicular to and parallel with a said predetermined Magnetic Field Generation with Particle Enhancement with Charge-based Absorption perpendicular to and parallel with a said predetermined particular type of coil configuration.

Alternatively, in a plurality of said predetermined number of space parallel with and perpendicular to predetermined number of side of said predetermined number of particular type of Coil and a said predetermined Magnetic Field Generation with Particle Enhancement with Charge-based Absorption perpendicular to and parallel with said predetermined number of particular type of Coil, perpendicular to and parallel to said predetermined particular type of Outer Housing and said predetermined particular type of Outer Housing Lid, on a plurality of predetermined side, on a plurality of predetermined edge, and on a plurality of predetermined surface, is present within and without a plurality of said predetermined number of space, there is a predetermined concentration of particular type of series of ion, with a predetermined particular type of characteristic of ion and a predetermined particular type of characteristic composition of series of ion of a predetermined polarity that are present at position within a said predetermined plurality of space of a said predetermined Magnetic Field Generation with Particle Enhancement with Charge-based Absorption, a said predetermined number of particular type of coil, a said Outer Housing and a said Outer Housing Lid from a predetermined particular type of outside source. These said plurality of predetermined space are of a predetermined size, a predetermined width, a predetermined length and a predetermined height that surround a said predetermined number of particular type of coil and on a plurality of predetermined side from and to a plurality of predetermined edge and from and to a plurality of predetermined surface for entire predetermined length of, predetermined width of and predetermined height of a said predetermined Magnetic Field Generation with Particle Enhancement with Charge-based Absorption, a said predetermined particular type of Upper Coil, a said predetermined particular type of Lower Coil, a said predetermined particular type of Outer Housing and a said predetermined particular type of Outer Housing lid. These said plurality of predetermined space assist in concentrating a predetermined concentration of said predetermined particular type of particle and predetermined particular type of concentration of ion with predetermined particular type of characteristic, and predetermined polarity, and predetermined particular type of characteristic behavior to a said predetermined particular type of consolidation leading to a predetermined particular type of concentration which creates a predetermined particular type of genesis and taking a predetermined formation of a said predetermined Magnetic Field Generation with Particle Enhancement with Charge-based Absorption that helps to form a predetermined particular type of characteristic Plasma Field comprising of predetermined particular type of number of characteristic ion and predetermined particular type of number of characteristic particle of a predetermined polarity, with a predetermined particular type of characteristic, a predetermined particular type of magnetic/electrical Field of a predetermined particular type of characteristic composition and a predetermined particular type of strength that grow stronger in predetermined particular type of density as more predetermined particular type of and predetermined number of series of Ion and predetermined particular type of number of Particle are positioned in a predetermined particular type of characteristic configuration within a predetermined particular type of charge-based platform magnetic/electrical Field which form and energize within said predetermined particular type of Outer Housing and said predetermined Outer Housing Lid that assist in the predetermined particular type of characteristic absorption and predetermined particular type of characteristic transfer of a said predetermined particular type of charge-based energy through predetermined particular type of number of characteristic linear exchange and predetermined particular type of number of characteristic non-linear exchange from outside said Magnetic Field Generation with Particle Enhancement with Charge-based Absorption to inside Magnetic Field Generation with Particle Enhancement with Charge-based Absorption, to within a said predetermined Magnetic Field Generation with Particle Enhancement with Charge-based Absorption, for predetermined particular type of characteristic absorption and predetermined particular type of characteristic transferring of a said predetermined charge-based energy into a said predetermined internal plurality of particular type of internal component comprising of a said plurality of said particular type of part, as desired by the user, that, in this particular embodiment of the present invention but not limited to, has a said predetermined particular type of number of absorbefacient/conductive property comprising of a said Magnetic Field Generation with Particle Enhancement with Charge-based Absorption with a said predetermined particular type of Upper Coil and a said predetermined particular type of Lower Coil, a said plurality of predetermined particular type of characteristic interlacing magnetic/electrical Field and predetermined particular type of characteristic interacting a said predetermined particular type of charge-based magnetic/electrical Field and a said predetermined Magnetic Field Generation with Particle Enhancement with Charge-based Absorption.

Alternatively, a said predetermined outside charge-based energy source supplying said Magnetic Field Generation with Particle Enhancement with Charge-based Absorption may, for example, be a direct current (DC), in this particular embodiment of the present invention. A particular type of converter can be used, as desired by the user, to change DC current into any other particular type of type of current. A said predetermined direct current (DC) flows through said wires with a said predetermined amount of particular type of charge-based energy, for example a predetermined amperage with a predetermined voltage in this particular embodiment of the present invention, a said predetermined polarity and in a said predetermined direction. A said predetermined particular type of outer charge-based energy source flows, in a predetermined direction, through said predetermined particular type of magnetic/electrical wire which comprises of the formation of a said plurality of predetermined particular type of characteristic charge-based energy Field used of varying power, of a predetermined varying strength, of a predetermined varying movement, of a predetermined varying composition and a said predetermined polarity in a predetermined direction. These said plurality of predetermined particular type of charge-based magnetic/electrical Field of a said plurality of said predetermined particular type of Coil start to said predetermined particular type of characteristic interlace and said predetermined particular type of characteristic interact with each other and with said predetermined particular type of charge-based magnetic/electrical Field surrounding a said predetermined Magnetic Field Generation with Particle Enhancement with Charge-based Absorption with a said plurality of predetermined particular type of charge-based magnetic/electrical Field. While a said plurality of predetermined particular type of charge-based magnetic/electrical Field characteristically interlaces with another predetermined particular type of charge-based magnetic/electrical Field, a said plurality of predetermined particular type of charge-based magnetic Field start to said characteristically particular type of interact with another particular type of charge-based magnetic/electrical Field and said plurality of predetermined particular type of charge-based magnetic/electrical Field, or as many as needed as desired by the user, and then form a predetermined characteristic Magnetic Field Generation with Particle Enhancement with Charge-based Absorption to characteristically interact with. Said predetermined number of space, as determined by the user, assist with the transfer of energy from dark energy, also known as particular type of Particle Field or Quantum Field with the Quantum Realm, from other predetermined particular type of energy field present in said particular type of environment and in said universe by allowing a said predetermined particular type of charge-based magnetic/electrical Field to form within said predetermined number of space.

Alternatively, the plurality of a said predetermined particular type of charge-based magnetic/electrical Field said characteristically particular type of interlace and said characteristically particular type of interact with said predetermined particular type of number of charge-based particle of predetermined polarity, of a predetermined number of charge characteristic, of a predetermined number of energy characteristic and of a predetermined number of chemical characteristic. A predetermined particular type of charge-based magnetic/electrical Field and a predetermined particular type of charge-based energy charge present within said predetermined particular type of Outer Housing and said predetermined particular type of Outer Housing Lid, start to said characteristically interact with plurality of said predetermined particular type of charge-based magnetic/electrical Field of said predetermined particular type of Upper Coil and predetermined particular type of Lower Coil. The particular type of flow of a said predetermined particular type of charge-based energy comprises of a said plurality of said predetermined particular type of wire of a said predetermined particular type of Coil and a number of Coil comprising of the particular type of movement of a said plurality of said predetermined particular type of charge-based magnetic/electrical Field around a plurality of predetermined side, a plurality of predetermined edge and a plurality of predetermined surface comprising of a predetermined length, of a predetermined width and of a predetermined height of said predetermined Magnetic Field Generation with Particle Enhancement with Charge-based Absorption. Once a said predetermined particular type of movement of a said predetermined particular type of characteristic interlacing and a said predetermined particular type of characteristic interaction of a said predetermined plurality of a said predetermined particular type of charge-based magnetic/electrical Field occur, the formation as a particular type of part of a said predetermined particular type of charge-based platform magnetic/electrical Field with Magnetic Field Generation with Particle Enhancement with Charge-based Absorption that begin to form around and within the said predetermined particular type of Coil leading to increased said characteristic particular type of interlacing with a said predetermined particular type of Particle Field or said predetermined Quantum Field within the Quantum Realm leading to a said characteristic particular type of interaction with a said predetermined Quantum Field within the Quantum Realm. A said predetermined particular type of Particle Field or said predetermined particular type of Quantum Field within the Quantum Realm is then accessed and a said predetermined particular type of internal component system comprising of a said plurality of particular type of part that have a said predetermined number of a particular type of absorbefacient/conductive property begin to absorb a said predetermined particular type of charge-based Energy from a said predetermined particular type of Particle Field or said predetermined particular type of Quantum Field within the Quantum Realm and characteristically particular type of transfer a said predetermined particular type of charge-based energy from said predetermined particular type of Particle Field or said predetermined particular type of Quantum Field within the Quantum Realm to a said predetermined number of a particular type of absorbefacient/conductive system which allow a said predetermined particular type of charge-based Energy to flow, so it can be used by the user as desired, or placed into a said predetermined particular type of storage containment system for future use, as desired by the user.

Objects, advantages, novel features, alternatives, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims.

### BRIEF DESCRIPTION OF SEVERAL VIEWS OF THE DRAWINGS

The following is a brief description of several views of the drawings that describes only one embodiment of the present invention, but not limited to, of the Magnetic Field Generation with Particle Enhancement with Charge-based Absorption. The accompanying drawings, which are incorporated into and form a part of the specification, illustrate one or more embodiments of the present invention and, together with the description, serve to explain the principles of the invention. The drawings are only for the purpose of illustrating one or more preferred embodiments of the invention and are not to be construed as limiting the invention in any way. In these drawings:

FIG. 1 shows an Exploded Perspective View of an embodiment of the present invention;

FIG. 2, 2A, and 2B shows a Top View with a Side View with a partial cut-out perspective that shows a said predetermined particular type of Upper Coil and a said predetermined particular type of Lower Coil, a said predetermined particular type of Torus, a said predetermined Magnetic Field Generation with Particle Enhancement with Charge-based Absorption, and a said predetermined particular type of Outer Housing with a said predetermined particular type of Outer Housing Lid of the present invention;

FIG. 3, 3A, and 3B shows a Side View of a predetermined said particular type of Upper Coil and a predetermined said lower coil that resides within the invention that shows a said predetermined charge-based magnetic/electrical field emitting, but is only one partial representation of a complete illustration of predetermined particular type of charge-based magnetic/electrical field surrounding a predetermined Magnetic Field Generation with Particle Enhancement with Charge-based Absorption on a plurality of side comprising of a predetermined width, of a predetermined length and of a predetermined height, a predetermined detail view of the Magnetic Field Generation with Particle Enhancement with Charge-based Absorption, and a predetermined particular type of charge-based magnetic/electrical flow of the present invention;

FIG. 4, 4A and 4B shows of the said predetermined particular type of Upper Coil, said predetermined particular type of Lower Coil and said predetermined particular type of Torus with one representation of the said predetermined particular type of charge-based magnetic/electrical Field flow and predetermined particular type of pathway with a number of pathway and said one representation of predetermined number of a particular type of charge-based magnetic/electrical field flow and predetermined particular type of pathway and a predetermined number of pathway of the said predetermined particular type of Upper Coil, said predetermined particular type of Torus and said predetermined particular type of Lower Coil of the present invention;

FIG. 5, 5A, 5B and 5C shows a Side View and a Detail Drawing of predetermined particular type of charge-based magnetic/electrical flow and predetermined number of pathway, predetermined particular type of series of ion and a predetermined number of ion present surrounding said predetermined particular type of Upper Coil, said predetermined particular type of Lower Coil, said predetermined particular type of Torus, of the present invention;

FIG. 6, 6A, 6B, and 6C shows a Top View, a Side Cut-Out View with a Detail View of the said Magnetic Field Generation with Particle Enhancement with Charge-based Absorption, the said predetermined particular type of Upper Coil, the said predetermined particular type of Torus, the said predetermined particular type of Lower Coil, the said predetermined particular type of Outer Housing, and the said predetermined particular type of Outer Housing Lid. A Top View of the said predetermined Magnetic Field Generation with Particle Enhancement with Charge-based Absorption, the said predetermined particular type of charge-based magnetic/electrical flow, the said predetermined characteristic particular type of ionic interaction, the said predetermined number of characteristic particular type of linear exchange and the said predetermined number of characteristic particular type of non-linear exchange, the predetermined particular type of charge-based magnetic/electrical field flow and predetermined number of charge-based particular type of magnetic/electrical pathway with predetermined characteristic particular type of interacting behavior and predetermined characteristic particular type of interlacing behavior that create a predetermined particular type of charge-based platform magnetic/electrical Field of predetermined number of characteristic particular type of linear ionic directional behavior for particular type of charge-based energy absorption. This is to show the structure inside and outside of the present invention;

### DETAILED DESCRIPTION OF THE INVENTION

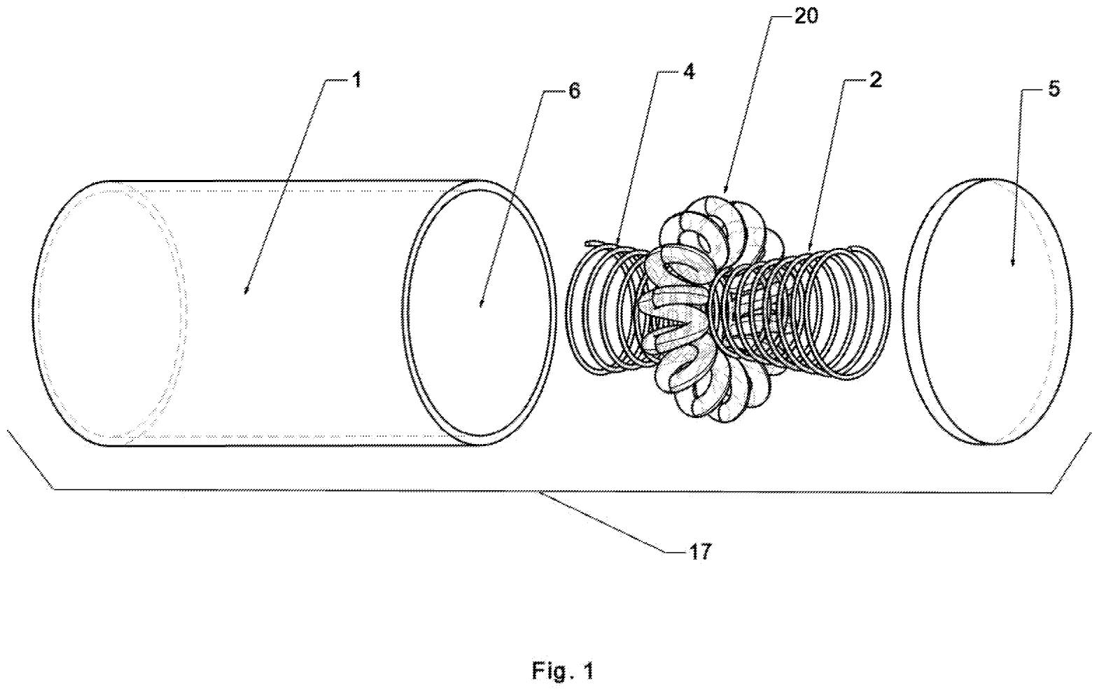

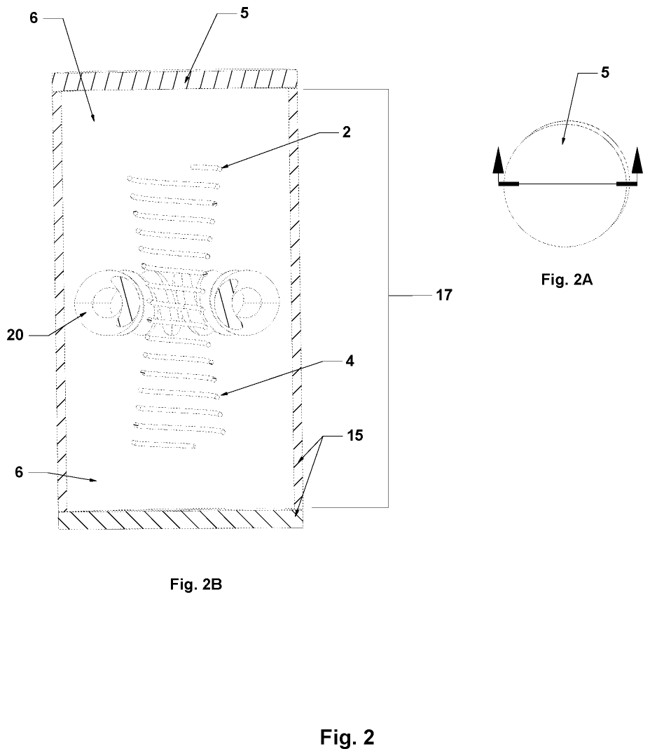

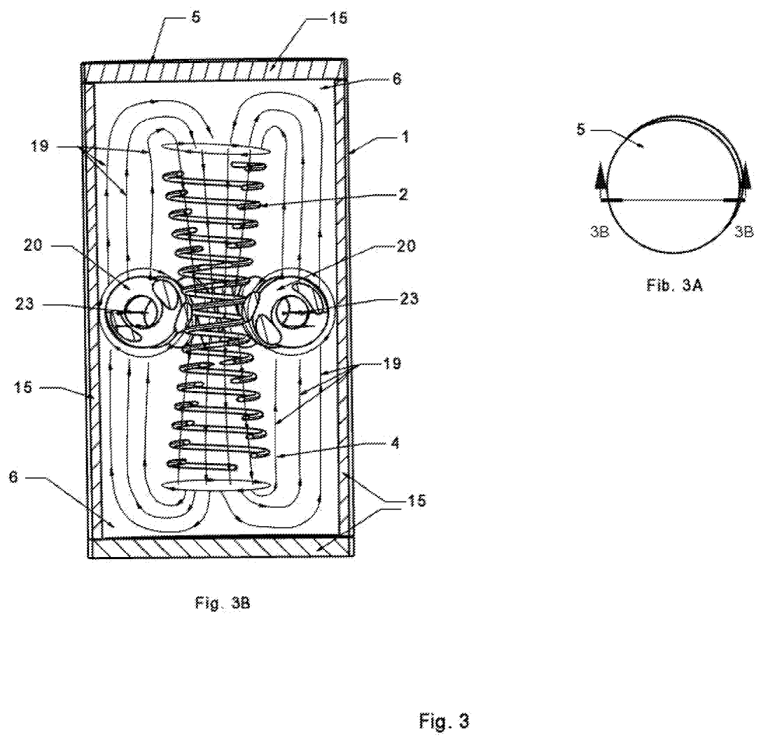

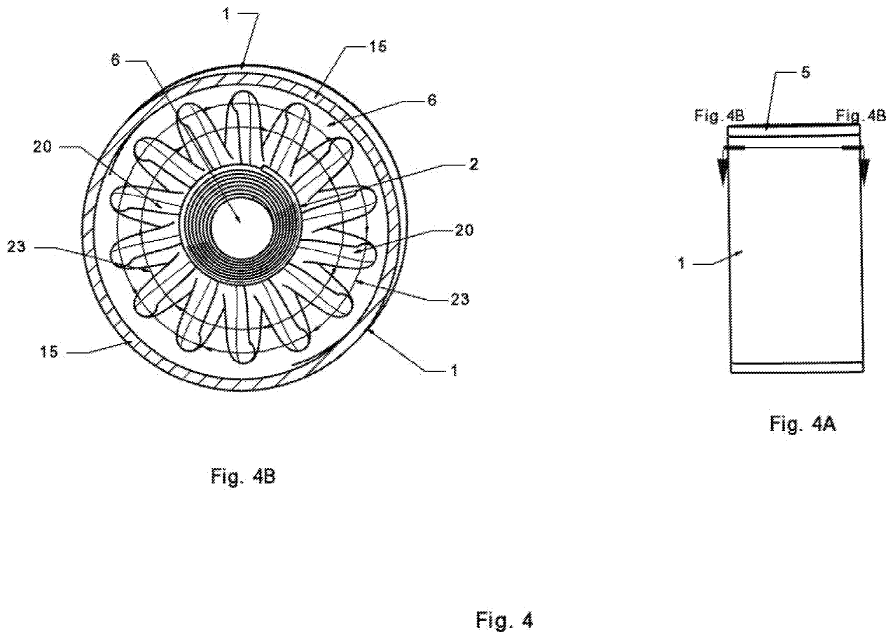

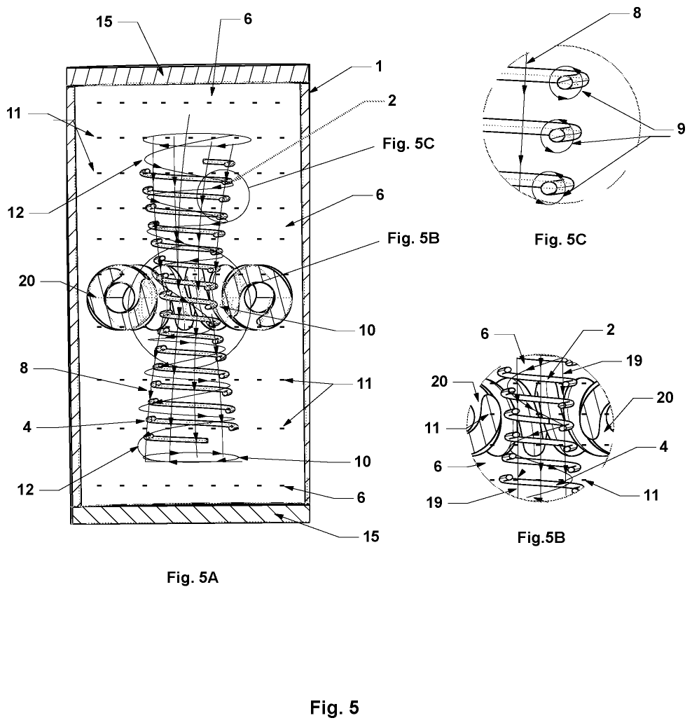

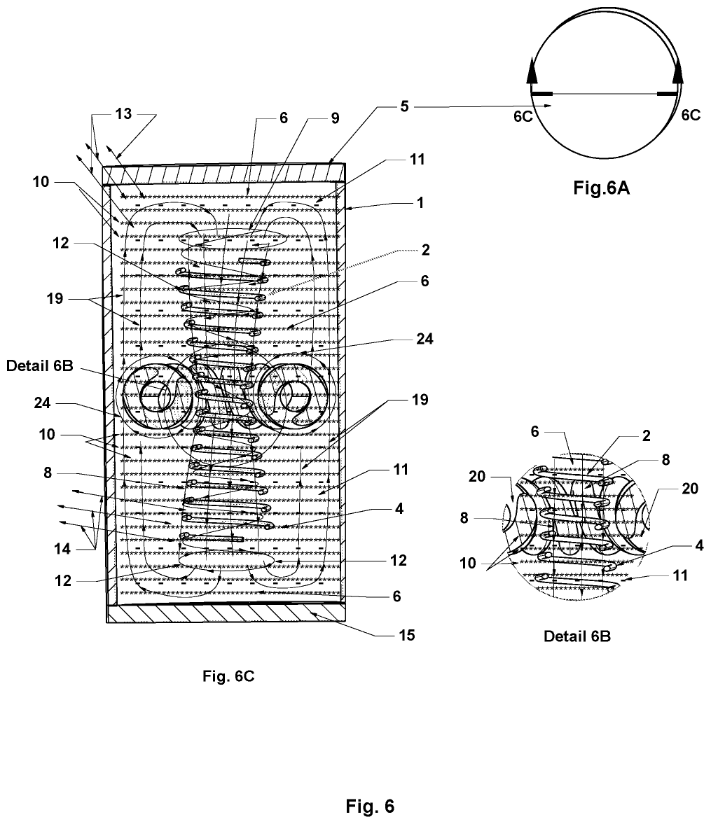

In this particular embodiment of the present invention, FIGS. 1-6 illustrate a said Magnetic Field Generation with Particle Enhancement with Charge-based Absorption Unit 17. A said Magnetic Field Generation with Particle Enhancement with Charge-based Absorption Unit 17 unit has a said predetermined particular type of Outer Housing 1 and a said predetermined particular type of Outer Housing Lid 5 formed to a predetermined shape, for example, a predetermined circular shape of a predetermined size, to a predetermined diameter, in this particular embodiment, from a predetermined particular type of non-conductive material, for example, a predetermined particular type of composite ceramic material 15, as seen in FIGS. 2, 3, 4, 5, and 6, in this particular embodiment, or other predetermined particular type of material that are available that would be suitable alternative embodiments of the subject matter of the disclosure. Those in the art will understand that in any suitable material, now known or hereafter developed may be used in the present embodiment described herein. In FIGS. 1, 2, 3 ,4, 5, and 6, there is within a said predetermined particular type of Outer Housing 1, and a said predetermined particular type of Outer Housing Lid 5, placed running a predetermined length, a predetermined width and a predetermined height of said predetermined outer housing 1, including a said predetermined particular type of Outer Housing Lid 5, a predetermined particular type of composite ceramic composition, a predetermined concentration and a predetermined particular type of configuration of a said predetermined particular type of composite ceramic material 15, as seen in FIGS. 2, 3, 4, 5, and 6, within and throughout a said predetermined particular type of Outer Housing 1 and said predetermined particular type of Outer Housing Lid 5, following a predetermined circular path radially outward with a said predetermined width, said predetermined length and said predetermined height around entire said predetermined particular type of Outer Housing 1 and a said predetermined particular type of Outer Housing Lid 5. Within a said Magnetic Field Generation with Particle Enhancement with Charge-based Absorption Unit 17, as shown best in FIG. 5 and FIG. 6, there is a said predetermined particular type of Torus 20. In this particular embodiment, but not limited to, a said predetermined particular type of Upper Coil 2, a said predetermined particular type of Lower Coil 4, and a said predetermined particular type of Torus 20, that assist in particular type of absorbing particular type of charge-based energy within the predetermined Magnetic Field Generation with Particle Enhancement with Charge-based Absorption Unit 17, by assisting in the formation of a predetermined particular type of charge-based platform magnetic/electrical Field 10, best seen in FIG. 5, and FIG. 6, which causes a predetermined particular type of charge-based platform magnetic/electrical Field within predetermined particular type of Outer Housing 1, and predetermined particular type of Outer Housing Lid 5, of the Magnetic Field Generation with Particle Enhancement with Charge-based Absorption Unit 17, to form a predetermined particular type of charge-based platform magnetic/electrical field 10, which allow for predetermined particular type of access to the predetermined particular type of Particle Field, or a particular type of Quantum Field within the Quantum Realm, or any other predetermined particular type of fields as desired by the user. In this particular embodiment of the present invention, but not limited to, a said predetermined particular type of Upper Coil 2, with a said predetermined particular type of Torus 20, and a said predetermined particular type of Lower Coil 4, are used to assist in the formation of a predetermined particular type of charge-based platform magnetic/electrical Field 10, within the Magnetic Field Generation with Particle Enhancement with Charge-based Absorption Unit 17 that will further assist the said predetermined particular type of Upper Coil 2, the said predetermined particular type of Lower Coil 4 and a said predetermined particular type of Torus 20, to acquire the predetermined particular type of charge-based energy from the predetermined particular type of Particle Field, or particular type of Quantum Field within the Quantum Realm. A said predetermined particular type of charge-based magnetic/electrical field 12 of a said predetermined particular type of Upper Coil 2 and a said predetermined particular type of charge-based magnetic/electrical field 12 of a predetermined Lower Coil 4, as best seen in FIG. 5 and FIG. 6, is produced by the predetermined flow of predetermined number of particular type of electron flowing through a said predetermined particular type of magnetic/electrical wire of a predetermined size at a predetermined particular type of charge-based energy at a predetermined strength, as desired by the user. Allowing predetermined number of particular type of negative ion 11, or any other predetermined number of species of ion, as desired by the user, to said predetermined characteristic particular type of interlace and said predetermined characteristic particular type of interact with a predetermined particular type of charge-based platform magnetic/electrical Field 10 within and without said predetermined particular type of Upper Coil 2, within and without said predetermined particular type of Lower Coil 4, and within and without said predetermined particular type of Torus 20. This predetermined particular type of formed charge-based platform magnetic/electrical Field 10 that form with said predetermined particular type of Upper Coil 2, with said predetermined particular type of Lower Coil 4, and said predetermined Torus 20, and said predetermined particular type of number of negative ion 11, or any other predetermined number of species of ion, as desired by the user, allow a said predetermined particular type of charge-based energy to be formed and produced, or as desired by the user. A said predetermined particular type of Torus 20 is of a predetermined diameter, as desired by the user, which is shown in FIGS. 1, 2, 3, 4, 5, and 6, that is used for assisting in the predetermined particular type of selection of a said predetermined particular type of charge-based magnetic/electrical absorption of a predetermined particular type of charge-based energy from a said predetermined particular type of charge-based magnetic/electrical field. A said predetermined Magnetic Field Generation with Particle Enhancement with Charge-based Absorption unit 17 with predetermined particular type of characteristic magnetic/electrical field strength and predetermined particular type of characteristic ionic field strength on a plurality of predetermined side, a plurality of predetermined edge and a plurality of predetermined surface of a said predetermined particular type of Upper Coil 2, said predetermined particular type of Lower Coil 4, and said predetermined particular type of Torus 20. A said predetermined Magnetic Field Generation with Particle Enhancement with Charge-based Absorption Unit 17 around sinuous spiral diameter of said predetermined particular type of Upper Coil 2, said predetermined particular type of Lower Coil 4, and said predetermined particular type of Torus 20 in a, for example, a predetermined sinuous spiral configuration, in this particular embodiment, extending from a predetermined starting point on a said predetermined particular type of Upper Coil 2, said predetermined particular type of Lower Coil 4, and said predetermined particular type of Torus 20, following a predetermined sinuous spiral length around said predetermined particular type of Upper Coil 2, said predetermined particular type of Lower Coil 4, and said predetermined particular type of Torus 20 to a predetermined endpoint opposite a starting point on a said predetermined particular type of Upper Coil 2, said predetermined particular type of Lower Coil 4, and said predetermined particular type of Torus 20 with a predetermined width, a predetermined length and a predetermined height, or as predetermined by the user. A said predetermined particular type of Upper Coil 2 emits a said predetermined particular type of charge-based magnetic/electrical Field 7 and a said predetermined particular type of charge-based magnetic/electrical Field 12 at a predetermined starting point opposite said predetermined particular type of Upper Coil 2, predetermined particular type of Lower Coil 4, and said predetermined particular type of torus 20, along a predetermined sinuous spiral length of a said predetermined particular type of Upper Coil 2, said predetermined particular type of Lower Coil 4, and said predetermined particular type of Torus 20, from both endpoint, opposite predetermined starting point, of a said predetermined particular type of Upper Coil 2, predetermined particular type of Lower Coil 4, and said predetermined particular type of Torus 20 within a predetermined area of space 6, as a representation in this particular embodiment, of a predetermined height, of a predetermined width and of a predetermined length, or as desired by the user. The design of a said predetermined particular type of Upper Coil 2, predetermined particular type of Lower Coil 4, and said predetermined particular type of Torus 20, follows a predetermined configuration in this particular embodiment, as shown best in FIGS. 3, 4, 5, and 6, with a predetermined starting point at an end of said predetermined particular type of Upper Coil 2 following the predetermined sinuous spiral configuration said predetermined particular type of Upper Coil 2 to starting point opposite at the end of the sinuous spiral turn and ending with the starting end of the said predetermined Lower Coil 4 which follow a predetermined particular type of path that follows a predetermined length, with a predetermined width with a predetermined height from a plurality of side of said predetermined particular type of Outer Housing 1 of a said Magnetic Field Generation with Particle Enhancement with Charge-based Absorption Unit 17. The predetermined number of particular type of said absorbefacient/conductive material may be increased or decreased, as determined by the user, depending on the predetermined particular type of charge-based energy need.

The said predetermined sinuous spiral configuration of said predetermined upper coil 2 that has predetermined number of particular type of characteristic absorbefacient/conductive property and said predetermined lower coil 4 that has predetermined number of particular type of characteristic absorbefacient/conductive property best seen in FIGS. 5 & 6, that assist in the particular type of absorption of a said predetermined particular type of charge-based magnetic/electrical species of ionic energy, by assisting in the creation of a Magnetic Field Generation with Particle Enhancement with Charge-based Absorption unit 17. A said particular type of internal component system of a said Magnetic Field Generation with Particle Enhancement with Charge-based Absorption unit 17 comprise of a said plurality of particular type of part, as shown in FIGS. 1-6, that have a said predetermined number of particular type of characteristic absorbefacient/conduction property that assist in the particular type of absorption of a said predetermined particular type of ionic energy from a said particular type of Particle Field or Quantum Field from within the Quantum Realm with a said predetermined number of particular type of characteristic linear exchange 14, a said predetermined number of particular type of characteristic non-linear exchange 13 as shown in FIG. 6. A said predetermined number of particular type of internal component of a said Magnetic Field Generation with Particle Enhancement with Charge-based Absorption Unit 17 comprising of a said predetermined a said Upper Coil 2, a said predetermined lower coil 4 and a said predetermined particular type of Torus 20.

A said predetermined number of space 6 as shown in FIGS. 1, 2, 3, 4, 5, and 6, is a predetermined number of space that is a predetermined distance radially outward from a said predetermined Magnetic Field Generation with Particle Enhancement with Charge-based Absorption Unit 17 that is perpendicular to and parallel with said predetermined Magnetic Field Generation with Particle Enhancement with Charge-based Absorption unit 17 on a plurality of said predetermined side, a plurality of said predetermined edge and a plurality of said predetermined surface of a said predetermined Magnetic Field Generation with Particle Enhancement with Charge-based Absorption unit 17 and follow a predetermined length of a said predetermined Magnetic Field Generation with Particle Enhancement with Charge-based Absorption Unit 17 from a predetermined starting point, of said predetermined Magnetic Field Generation with Particle Enhancement with Charge-based Absorption Unit 17 following a said predetermined sinuous spiral path along a predetermined length of said predetermined Magnetic Field Generation with Particle Enhancement with Charge-based Absorption Unit 17 perpendicular to and parallel with a said Magnetic Field Generation with Particle Enhancement with Charge-based Absorption Unit 17, a said predetermined sinuous spiral path around said predetermined Magnetic Field Generation with Particle Enhancement with Charge-based Absorption Unit 17, along entire said predetermined length of a said predetermined Magnetic Field Generation with Particle Enhancement with Charge-based Absorption Unit 17 to the other said predetermined endpoint opposite a starting point of a said predetermined Magnetic Field Generation with Particle Enhancement with Charge-based Absorption Unit 17. A said predetermined Magnetic Field Generation with Particle Enhancement with Charge-based Absorption Unit 17 opposite of a said predetermined starting point, a predetermined distance, and a predetermined alignment of a said predetermined particular type of charge-based platform magnetic/electrical Field 10 of a said predetermined Magnetic Field Generation with Particle Enhancement with Charge-based Absorption Unit 17. A said predetermined Magnetic Field Generation with Particle Enhancement with Charge-based Absorption Unit 17 is placed within a said predetermined particular type of Outer Housing 1 perpendicular to and parallel with a said predetermined particular type of Outer Housing 1 and perpendicular to and parallel with a said predetermined particular type of Outer Housing Lid 5. A said predetermined Magnetic Field Generation with Particle Enhancement with Charge-based Absorption Unit 17 from a predetermined starting point, as desired by the user, of a said predetermined equal distance from a predetermined starting point of a said predetermined Magnetic Field Generation with Particle Enhancement with Charge-based Absorption Unit 17 to a said predetermined particular type of Outer Housing Lid 5. A said predetermined Magnetic Field Generation with Particle Enhancement with Charge-based Absorption Unit 17 is of a said predetermined equal distance from a plurality of predetermined side of a said predetermined particular type of Outer Housing 1 and said predetermined particular type of Outer Housing Lid 5, a plurality of said predetermined edge and a plurality of said predetermined surface along the entire predetermined length of a said predetermined Magnetic Field Generation with Particle Enhancement with Charge-based Absorption unit 17 as seen in FIGS. 2, 3, 4, 5, and 6.

A said predetermined Upper Coil 2 is perpendicular to and parallel with a said predetermined Magnetic Field Generation with Particle Enhancement with Charge-based Absorption Unit 17 on a plurality of said predetermined side, a plurality of said predetermined edge and a plurality of said predetermined surface of a said predetermined Magnetic Field Generation with Particle Enhancement with Charge-based Absorption Unit 17. A said predetermined Upper Coil 2 start from a predetermined starting point, as predetermined by the user, that is perpendicular to and parallel with said Magnetic Field Generation with Particle Enhancement with Charge-based Absorption Unit 17, and said predetermined sinuous spiral configuration, in this particular embodiment, radially outward with said predetermined wire, one said predetermined particular type of magnetic/electrical wire beside another said predetermined particular type of magnetic/electrical wire with a plurality of layer, for example, in a predetermined sinuous spiral manner, in this particular embodiment, of said predetermined equal distance apart from a said predetermined magnetic/electrical wire beside said predetermined particular type of magnetic/electrical wire thereafter, with a said predetermined opening of a said predetermined size. Each said predetermined particular type of magnetic/electrical wire of a said predetermined Upper Coil 2 is a said predetermined equal distance within a said Magnetic Field Generation with Particle Enhancement with Charge-based Absorption Unit 17, a plurality of said predetermined edge and a plurality of said predetermined surface of a said predetermined particular type of Outer Housing 1 with said predetermined particular type of magnetic/electrical wire that is, preferably without any type of insulating covering in this particular embodiment, of a said predetermined magnetically/electrically conductive material of a said predetermined particular type of characteristic composition that, for example, may contain copper, in this particular embodiment, or any combination of predetermined particular type of charge-based energy transfer material for a predetermined particular type of charge-based energy transfer, as desired by the user, that winds in a said predetermined sinuous spiral configuration, in this particular embodiment, that by smaller predetermined incremented measurements in a said predetermined sinuous spiral configuration toward said predetermined particular type of Upper Coil 2 to a predetermined outermost edge of a predetermined sinuous spiral point of said predetermined particular type of magnetic/electrical wire, to a said predetermined size that end with a predetermined opening at a predetermined endpoint that is opposite a predetermined starting point of a said predetermined Upper Coil 2 that are of said equal distance from a predetermined number of predetermined side, a predetermined number of predetermined edge and a predetermined number of predetermined surface of a said predetermined particular type of Outer Housing 1 and a said predetermined particular type of Outer Housing Lid 5.

The predetermined particular type of charge-based energy that is used from a said predetermined particular type of outside source and flows through said predetermined particular type of magnetic/electrical wire of a said predetermined Upper Coil 2, which is predetermined by the user, create a predetermined number of particular type of charge-based magnetic/electrical Field 8 and predetermined number of particular type of charge-based magnetic/electrical Field 12 of Magnetic Field Generation with Particle Enhancement with Charge-based Absorption Unit, as shown in FIGS. 5 and 6, that surround a plurality of said predetermined particular type of magnetic/electrical wire and a said predetermined Upper Coil 2 on a plurality of predetermined side, a plurality of predetermined edge and a plurality of predetermined surface as it wind in a said predetermined direction and a said predetermined particular type of charge-based magnetic/electrical energy Field 8 and said predetermined particular type of charge-based magnetic/electrical Field 12 of a said predetermined Upper Coil 2 which energize to a predetermined particular type of charge-based energy a said predetermined number of space surrounding a said predetermined Upper Coil 2 with a predetermined polarity and a predetermined characteristic particular type of charge to assist in a said predetermined characteristic particular type of interlacing and a said predetermined characteristic particular type of interaction with other said predetermined particular type of charge-based magnetic/electrical Field 8 and said predetermined particular type of charge-based magnetic/electrical Field 12 of said predetermined Lower Coil 4 of Magnetic Field Generation with Particle Enhancement with Charge-based Absorption Unit, as seen in FIGS. 5 and 6, that surround a plurality of said predetermined particular type of magnetic/electrical wire and said predetermined Lower Coil 4 on a plurality of predetermined side, a plurality of predetermined edge and a plurality of predetermined surface as it wind in a said predetermined sinuous spiral direction and a said predetermined particular type of charge-based magnetic/electrical Field 8 and said predetermined particular type of charge-based magnetic/electrical Field 12 of a said predetermined Lower Coil 4 which energize a predetermined particular type of charge-based energy to a said predetermined number of space surrounding a said predetermined Lower Coil 4 with a predetermined polarity and a predetermined particular type of charge that assist in a said predetermined characteristic particular type of interlacing and a said predetermined characteristic particular type of interaction with other said predetermined particular type of charge-based magnetic/electrical Field 8 and said predetermined particular type of charge-based magnetic/electrical Field 12 of said predetermined Upper Coil 2, present within a said predetermined particular type of Outer Housing 1 and a said predetermined particular type of Outer Housing Lid 5.

A said predetermined number of space 6, as shown in FIGS. 1, 2, 3, 4, 5, and 6, that surround a said predetermined Torus 20, extending radially outward from a plurality of said predetermined side, a plurality of said predetermined edge and a plurality of said predetermined surface of a said predetermined particular type of Torus 20, and is perpendicular to and parallel with a said predetermined length of a said predetermined particular type of Upper Coil 2, and said predetermined particular type of Torus 20, from and to a said predetermined particular type of Upper Coil 2 on a plurality of said predetermined side, a plurality of said predetermined edge and a plurality of said predetermined surface of a said predetermined particular type of Upper Coil 2 from a said predetermined starting point, as determined by the user, of a said predetermined particular type of Upper Coil 2 and a said predetermined number of space 6 in a predetermined size following a said predetermined length of a said predetermined particular type of Upper Coil 2 to a said predetermined endpoint opposite a predetermined starting point of a said predetermined particular type of Upper Coil 2. A said predetermined number of space 6 that is shown in FIGS. 1, 2, 3, 4, 5, and 6, between a said predetermined particular type of Upper Coil 2 and a said predetermined particular type of Torus 20, is one of a plurality of said predetermined number of space 6 that are used for a said predetermined characteristic particular type of interlacing and a said predetermined characteristic particular type of interaction of a said predetermined particular type of charge-based magnetic/electrical Field that has a said predetermined particular type of charge characteristics and a said predetermined number of chemical characteristics between a said predetermined particular type of Upper Coil 2 and said predetermined particular type of Torus 20. A said predetermined number of space 6 is of a said predetermined incremented measurements of distance between a said predetermined particular type of Torus 20, and a said predetermined particular type of Upper Coil 2 in width at top of a said predetermined particular type of Upper Coil 2 to the other said predetermined end of a said predetermined particular type of Upper Coil 2 where a said predetermined number of space 6 becomes a predetermined size perpendicular to and parallel with a length of a said predetermined particular type of Upper Coil 2 and perpendicular to and parallel with a said predetermined particular type of Torus 20. A said predetermined polarity, a said predetermined particular type of charge characteristics and a predetermined number of chemical characteristic that particular type characteristically interacts with a said predetermined particular type of charge-based magnetic/electrical Field 24 of a said predetermined particular type of Torus 20, and particular type characteristically interacts with a said predetermined particular type of charge-based magnetic/electrical Field 8 created by a said predetermined particular type of Upper Coil 2.

A said predetermined particular type of Lower Coil 4 is perpendicular to and parallel with said predetermined particular type of Torus 20, and is perpendicular to and parallel with said predetermined particular type of Upper Coil 2, and is perpendicular to and parallel with said Magnetic Field Generation with Particle Enhancement with Charge-based Absorption Unit 17 which runs parallel from a said predetermined starting point of a said predetermined particular type of Lower Coil 4, as predetermined by the user, along a predetermined length of a said predetermined particular type of Lower Coil 4 to a predetermined endpoint opposite a predetermined starting point of a said predetermined particular type of Lower Coil 4. A said predetermined particular type of Lower Coil 4 begins in a said predetermined sinuous spiral configuration outward with said predetermined particular type of wire, a said predetermined particular type of wire beside another said particular type of predetermined wire with a said plurality of predetermined layer of said predetermined particular type of wire, for example as seen with said predetermined particular type of Upper Coil 2 in this particular embodiment, as seen in FIGS. 1-6, of a said predetermined incremental measurement of distance apart from one said predetermined particular type of magnetic/electrical wire beside said predetermined particular type of magnetic/electrical wire thereafter, with a said predetermined opening of a predetermined size, from a said predetermined incremented measurement of distance on a plurality of side with a said predetermined distance perpendicular to and parallel with a plurality of side of a said predetermined particular type of Outer Housing 1 and a said predetermined particular type of Outer Housing Lid 5 with a said predetermined particular type of magnetic/electrical wire that is, for example, without any type of insulating covering in this particular embodiment, of a said predetermined number of magnetic/electrical particular type of property and a said predetermined number of absorbefacient/conductive particular type of property of a predetermined said particular type of composition that, for example, may be copper in this particular embodiment, or any combination of technology for characteristic particular type of charge-based energy transfer, now known or hereafter developed, as desired by the user, with a predetermined size and a predetermined shape, that is at a said predetermined incremental measurement of distance in a said predetermined sinuous spiral configuration, in this particular embodiment, that remain with said predetermined equal measurement with the same said predetermined size and end with a said predetermined opening at a said predetermined endpoint opposite a predetermined starting point that is of a said predetermined equal distance from a plurality of predetermined side, a plurality of predetermined edge and a plurality of predetermined surface radially outward to a said predetermined particular type of Outer Housing 1 and a said predetermined particular type of Outer Housing Lid 5.

A said predetermined particular type of charge-based Energy that is used from a said predetermined particular type of outside source and flow through a said predetermined particular type of magnetic/electrical wire of a said predetermined particular type of Upper Coil 2 through the said predetermined particular type of Upper Coil 2 and said predetermined particular type of Lower Coil 4 and flow through said predetermined particular type of Lower Coil 4, which is predetermined by the user, create a said predetermined particular type of charge-based magnetic/electrical Field 8 of said predetermined particular type of Upper Coil 2 and a said predetermined particular type of charge-based magnetic/electrical Field 8 of said predetermined particular type of Lower Coil 4 that surround a said predetermined particular type of magnetic/electrical wire as shown in FIG. 6C, which a said predetermined particular type of magnetic/electrical wire in plurality create a said predetermined particular type of charge-based magnetic/electrical Field 8 of said predetermined particular type of Upper Coil 2 and a said predetermined particular type of charge-based magnetic/electrical Field 8 of a said predetermined particular type of Lower Coil 4 that surround a said plurality of said predetermined particular type of magnetic/electrical wire and surround a said predetermined particular type of Lower Coil 4, on a plurality of predetermined side, a plurality of predetermined edge and a plurality of predetermined surface as it wind in a predetermined sinuous spiral in a said predetermined direction and a said predetermined particular type of charge-based magnetic/electrical Field 8 of said Upper Coil 2 and a said predetermined particular type of charge-based magnetic/electrical Field 8 of a said predetermined particular type of Lower coil 4 which energize a surrounding said predetermined number of space of a said predetermined particular type of Lower Coil 4 with a predetermined polarity and a predetermined particular type of characteristic charge that assist in the said predetermined characteristic particular type of interlacing and a said predetermined characteristic particular type of interaction with the other said predetermined particular type of charge-based magnetic/electrical Field 8 and predetermined particular type of charge-based magnetic/electrical Field 10 present within a said predetermined particular type of Outer Housing 1 and within a said predetermined particular type of Outer Housing Lid 5.

A said predetermined number of space 6 that is shown in FIGS. 1, 2, 3, 4, 5, and 6, between a said predetermined particular type of Upper Coil 2 and a said predetermined particular type of Lower Coil 4 is one of a said predetermined plurality of said predetermined number of space 6 that will allow for a said predetermined characteristic particular type of interaction and a said predetermined characteristic particular type of interlacing of predetermined particular type of charge-based magnetic/electrical Field 8 of said predetermined particular type of Upper Coil 2 and a said predetermined particular type of charge-based magnetic/electrical Field 8 of said Lower Coil 4. Within said predetermined number of space and throughout said predetermined number of space, a predetermined polarity, a predetermined particular type of charge characteristic and a predetermined particular type of chemical characteristic within a said predetermined particular type of Outer Housing 1 and a said predetermined particular type of Outer Housing Lid 5 from a predetermined particular type of outside source. A said predetermined number of space 6 has a said predetermined width which run perpendicular to and parallel with a said Magnetic Field Generation with Particle Enhancement with Charge-based Absorption Unit 17, perpendicular to and parallel with said predetermined particular type of Torus 20, perpendicular to and parallel with a said predetermined particular type of Upper Coil 2 and run radially outward in a predetermined plurality of direction and running the said predetermined length between a said predetermined particular type of Upper Coil 2 and a said predetermined particular type of Lower Coil 4. A said predetermined number of space 6 extending radially outward from a plurality of said predetermined side, a plurality of said predetermined edge and a plurality of said predetermined surface of a said predetermined Upper Coil 2 from and including a said predetermined particular type of Upper Coil 2 from a said predetermined starting point, as predetermined by the user, and perpendicular to and parallel with a said predetermined particular type of Lower Coil 4 and perpendicular to and parallel with a said predetermined particular type of Lower Coil 4, ending at a said predetermined endpoint opposite a predetermined starting point of a said predetermined particular type of Lower Coil 4. A said predetermined polarity, a said predetermined number of charge characteristic and a said predetermined number of chemical characteristic that said characteristically interlace and said characteristically interact with a said particular type of predetermined Torus 20, a said predetermined particular type of charge-based magnetic/electrical Field 8 and said predetermined particular type of charge-based magnetic/electrical Field 12 of a said predetermined particular type of Upper Coil 2 and with a said predetermined particular type of charge-based magnetic/electrical Field 8 and said predetermined particular type of charge-based magnetic/electrical Field 12 of a said predetermined particular type of Lower Coil 4. The said predetermined particular type of magnetic/electrical wire of a said predetermined particular type of Lower Coil 4 and a said predetermined particular type of Upper Coil 2 have a said predetermined sinuous spiral movement of a said predetermined particular type of charge-based magnetic/electrical Field 8, said predetermined particular type of charge-based magnetic/electrical Field 10, said predetermined particular type of charge-based magnetic/electrical Field 12, and said predetermined particular type of charge-based magnetic/electrical Field 24.

A said predetermined number of space 6 between a said predetermined particular type of Lower Coil 4 and a said predetermined particular type of Outer Housing 1 is of a predetermined distance radially on a plurality of said predetermined side, a said predetermined length, a said predetermined width, and a said predetermined height of a said predetermined particular type of Lower Coil 4 and a said predetermined particular type of Outer Housing 1 and a said predetermined particular type of Outer Housing Lid 5. A said predetermined number of space 6 has a said predetermined width running perpendicular to and parallel with a said Magnetic Field Generation with Particle Enhancement with Charge-based Absorption Unit 17, perpendicular to and parallel with a said predetermined particular type of Lower Coil 4 and perpendicular to and parallel with a said predetermined particular type of Outer Housing 1 and perpendicular and parallel to a predetermined particular type of Outer Housing Lid 5 and runs radially outward in a plurality of predetermined directions around said Magnetic Field Generation with Particle Enhancement with Charge-based Absorption Unit 17, from a said predetermined particular type of Outer Housing Lid 5 running perpendicular to and parallel with the predetermined length of a said predetermined particular type of Outer Housing 1 to the other end of a said predetermined particular type of Outer Housing 1 surrounding a said predetermined particular type of Torus 20, surrounding a said predetermined particular type of Upper Coil 2 and surrounding a said predetermined particular type of Lower Coil 4 in its entirety thereof.

A said predetermined particular type of charge-based magnetic/electrical Field 8 of a said predetermined particular type of Upper Coil 2, a said predetermined particular type of charge-based magnetic/electrical Field 8 of a said predetermined particular type of Lower Coil 4, with a said predetermined polarity, a predetermined number of charge characteristic and said predetermined particular type of charge-based magnetic/electrical Field 12 with a predetermined polarity and predetermined number of charge characteristic. The said predetermined particular type of charge-based magnetic/electrical Field of a said predetermined particular type of charge-based magnetic/electrical Field 8 of a said predetermined particular type of Upper Coil 2, a said predetermined particular type of charge-based magnetic/electrical Field 8 of a said predetermined particular type of Lower Coil 4 that characteristically interacts with a said predetermined particular type of charge-based magnetic/electrical Field 8 of a said predetermined particular type of Upper Coil 2 and a said predetermined particular type of charge-based magnetic/electrical Field 8 of a said predetermined particular type of Lower Coil 4. This particular type of characteristic interaction causes a said predetermined particular type of charge-based magnetic/electrical Field 12 to form within said predetermined particular type of Upper Coil 2 and a said predetermined particular type of charge-based magnetic/electrical Field 12 to form within said predetermined particular type of Lower Coil 4 that flows in a predetermined direction, the predetermined particular type of charge-based energy used, towards said predetermined particular type of Torus 20. The said predetermined particular type of charge-based magnetic/electrical Field 8 of a said particular type of predetermined Upper Coil 2 and the said predetermined particular type of charge-based magnetic/electrical Field 8 of a said predetermined particular type of Lower Coil 4 flow in a predetermined particular type of direction towards the said predetermined particular type of Torus 20, so as to characteristically particular type of interact and characteristically particular type of interlace at the center and through the said predetermined particular type of Torus 20.

A said predetermined particular type of charge-based magnetic/electrical wave carry a predetermined particular type of charge-based magnetic/electrical characteristic component that can be used for predetermined particular type of charge-based energy since predetermined particular type of charge-based magnetic/electrical energy is fed by the particular type of Quantum Field of the Quantum Realm or the particular type of Particle Field. Once separation of the characteristic predetermined number of particular type of linear exchange 14 and the characteristic predetermined number of particular type of non-linear exchange 13 occur when the said predetermined particular type of charge-based magnetic/electrical wave 8 of said predetermined particular type of Upper Coil 2 and predetermined particular type of charge-based magnetic/electrical wave 8 of a predetermined particular type of Lower Coil 4 characteristically particular type of interact within and without said predetermined particular type of Torus 20 and predetermined particular type of charge-based magnetic/electrical wave 24 of said predetermined particular type of Torus 20. The direction of particular type of charge-based energy flow, as desired by the user, is clockwise, for example in this particular embodiment, and create a predetermined particular type of characteristic rotation effect 12 as best seen in FIGS. 3, 5, and 6. This helps to absorb said particular type of characteristic charge-based energy due to said predetermined particular type of characteristic rotational effect 12 of the said predetermined particular type of charge-based magnetic/electrical wave 8 and said predetermined particular type of charge-based magnetic/electrical wave 8 characteristically particular type of interacting with the said predetermined particular type of charge-based platform magnetic/electrical Field 10 thereby characteristically particular type of interacts with the particular type of Quantum Field within the Quantum Realm or particular type of Particle Field, as desired by the user. The predetermined particular type of charge-based magnetic/electrical energy flowing through a said predetermined particular type of magnetic/electrical wire causes particular type of charge-based magnetic/electrical excitation of the area surrounding the predetermined particular type of magnetic/electrical wire 9. The said predetermined particular type of characteristic rotational effect of 12 of said predetermined particular type of Upper Coil 2 and the said predetermined particular type of characteristic rotational effect of 12 of the said predetermined particular type of Lower Coil 4 with the production of the said predetermined Magnetic Field Generation with Particle Enhancement with Charge-based Absorption Unit 17 causes the said predetermined Magnetic Field Generation with Particle Enhancement with Charge-based Absorption Unit 17 to appear at predetermined point and the said predetermined number of particular type of charge-based ion from the particular type of Quantum Field of the Quantum Realm or particular type of Particle Field are absorbed by said predetermined particular type of Upper Coil 2 and said predetermined Lower Coil 4. Characteristic particular type of Ionic charge-based energy flow into a said predetermined particular type of Upper Coil 2 and said predetermined particular type of Ionic charge-based energy flow into a said predetermined particular type of Lower Coil 4 thereby travelling through said predetermined particular type of magnetic/electrical wire after being absorbed by said predetermined particular type of magnetic/electrical wire.

A said Magnetic Field Generation with Particle Enhancement with Charge-based Absorption Unit 17 is now acting as a predetermined particular type of pass-through device for said particular type of Particle energy or particular type of Quantum energy within the Quantum Realm, as desired by the user, by a said predetermined characteristic number of particular type of linear exchange 14 to a said Magnetic Field Generation with Particle Enhancement with Charge-based Absorption Unit 17. The said predetermined number of particular type of linear exchange 14 are due to the said predetermined number of particular type of negative ion 11 arranging in the same characteristic particular type of linear direction within the said Magnetic Field Generation with Particle Enhancement with Charge-based Absorption Unit 17. The said predetermined number of characteristic particular type of non-linear exchange 13 are due to the said predetermined number of particular type of negative ion 11 becoming scattered or driven out of place and are predetermined number of particular type of free negative ion 11 that are roaming within the said predetermined particular type of charge-based ion cloud 10 of the said Magnetic Field Generation with Particle Enhancement with Charge-based Absorption Unit 17. A said particular type of Quantum energy within the Quantum Realm or particular type of Particle energy that has been absorbed and transferred by a said predetermined particular type of Upper Coil 2, absorbed and transferred by a said predetermined particular type of Lower Coil 4 and absorbed and transferred by a said predetermined particular type of Torus 20, to a said Magnetic Field Generation with Particle Enhancement with Charge-based Absorption Unit 17 is then placed into a said predetermined particular type of storage or it may be used immediately, as desired by the user.

A said particular type of charge-based energy flow through said predetermined particular type of magnetic/electrical wire of said predetermined particular type of Upper Coil 2, in a predetermined particular type of Torus 20, through to said predetermined particular type of Lower Coil 4. The said predetermined particular type of charge-based magnetic/electrical Field 8, said predetermined particular type of charge-based magnetic/electrical Field 10, said predetermined particular type of charge-based magnetic/electrical Field 12, and said predetermined particular type of charge-based magnetic/electrical Field 24 created moves in a predetermined direction at a predetermined speed, as desired by the user. As this predetermined movement occurs it cause the said predetermined number of particular type of negative charge 11 to begin predetermined particular type of alignment in the predetermined particular direction, as desired by the user. As this predetermined particular type of alignment occurs within the said predetermined particular type of charge-based magnetic/electrical Field 8 and the said particular type of predetermined charge-based magnetic/electrical Field 12 it becomes stronger and more pronounced. The said predetermined particular type of charge-based platform magnetic/electrical Field 10 begin to pull predetermined particular type of charge-based energy from the particular type of Particle Field or particular type of Quantum Field of the Quantum Realm, as desired by the user. This predetermined particular type of charge-based energy is absorbed by the predetermined particular type of charge-based platform magnetic/electrically aligned Field and is then transferred to the predetermined number of particular type of absorbefacient/conductive particular type of magnetic/electrical wiring after passing through the predetermined particular type of charge-based magnetic/electrical ion cloud. It then characteristically particular type of interacts and characteristically particular type of interweaves thereby creating the said predetermined Magnetic Field Generation with Particle Enhancement with Charge-based Absorption 17 and the said predetermined particular type of Upper Coil 2, the said predetermined particular type of Torus 20, and the said predetermined particular type of Lower Coil 4 for start the said particular type of absorption into said predetermined particular type of magnetic/electrical wire. The predetermined particular type of magnetic/electrical wire of said predetermined particular type of Upper Coil 2, said predetermined particular type of Torus 20, and said predetermined particular type of Lower Coil 4 has its own predetermined particular type of charge-based magnetic/electrical Field 8 surrounding. As the particular type of Particle Energy or particular type of Quantum Energy is absorbed by the said predetermined Magnetic Field Generation with Particle Enhancement with Charge-based Absorption Unit 17 through the Magnetic Field Generation with Particle Enhancement with Charge-based Absorption 17 to the said predetermined particular type of Upper Coil 2, to the said predetermined particular type of Torus 20, and to the said predetermined particular type of Lower Coil 4, the said predetermined particular type of charge-based energy is absorbed because of the particular type of alignment of the predetermined number of particular type of negative ion 11 with the predetermined number of particular type of magnetic/electrical line of the internal aspect of the said predetermined particular type of Upper Coil 2, the predetermined number of particular type of magnetic/electrical line of the internal aspect of the said predetermined particular type of Lower Coil 4, and the predetermined number of particular type of magnetic/electrical line of the internal aspect of the said predetermined particular type of Torus 20 thereby creating a characteristic particular type of vortex of alignment by the said predetermined particular type of Upper Coil 2, the said predetermined particular type of Torus 20, and said predetermined particular type of Lower Coil 4. As the said predetermined particular type of charge-based energy is absorbed by the said predetermined particular type of absorbefacient/conductive magnetic/electrical wire it is used by the particular type of system or placed into particular type of storage for future use or other means as desired by the user.

Although the invention has been described in detail with particular reference to these preferred embodiments, other embodiments can achieve the same results. Variations, alternatives, and modifications of the present invention will be obvious to those skilled in the art and it is intended to cover in the appended claims all such modifications and equivalents. The entire disclosures of all references, applications, patents, and publications cited above are hereby incorporated by reference.

What is claimed is:

1. A said Magnetic Field Generation with Particle Enhancement with Charge-based Absorption comprising of:
a said predetermined charge-based energy absorption that comprises of said predetermined magnetic/electrical properties and
a said predetermined charge-based energy absorption that comprises of said predetermined absorbefacient/conductive properties and
a predetermined number of said predetermined coil with a said predetermined wire of predetermined size, predetermined shape, and predetermined number of chemical characteristics for said predetermined charge-based magnetic/electrical energy transfer that is, for example, without any insulative covering, that has predetermined magnetic/electrically conductive properties with a predetermined composition that, for example, may be copper or any combination of technology now known or hereafter developed, used for charge-based energy absorption, with a predetermined size, with a predetermined shape and with a predetermined length and
a said predetermined Magnetic Field Generation with Particle Enhancement with Charge-based Absorption comprising of predetermined number of ion of a predetermined polarity and a predetermined number of magnetic/electrical charge-based energy field, with said predetermined polarity, a said predetermined number of field characteristic, a said predetermined charge characteristic and a said predetermined magnetic/electrical charge-based energy state that can be induced to produce a said predetermined magnetic/electrical charge-based field to a strength that is suitable and desired by the user and
a said predetermined charge-based magnetic/electrical energy absorption wherein a said predetermined casing comprises of a said predetermined absorbefacient/non-conductive component that is made of a predetermined number of composition of material, or suitable material, now known or hereafter developed, in the present embodiment described herein, may be used for the enhancement of energy absorption and
a said predetermined material that comprises of a said absorbefacient/conductive component of a predetermined composition that will assist with predetermined and a said charge-based magnetic/electrical energy absorption and predetermined charge-based magnetic/electrical transfer thereof and
a said predetermined number of coil used for said predetermined charge-based field creation and predetermined charge-based magnetic/electrical field stabilization and
a said predetermined number of charge-based platform magnetic/electrical field comprising of a predetermined absorbefacient/conductive charge-based magnetic/electrical field made from a said predetermined number of predetermined charge-based magnetic/electrical field that said predetermined characteristically interlace and said predetermined characteristically interact with predetermined magnetic/electrical charge-based energy field to create a said predetermined absorbefacient/conductive Magnetic Field Generation with Particle Enhancement with Charge-based Absorption which can access other types of predetermined number of charge-based magnetic/electrical field and
a said predetermined number of space of a predetermined size that assist in the predetermined creation and predetermined formation of said predetermined charge-based characteristic interlacing and said predetermined charge-based characteristic interaction of predetermined number of particle with said predetermined charge-based magnetic/electrical energy field within Magnetic Field Generation with Particle Enhancement with Charge-based Absorption and
a said predetermined charge-based magnetic/electrical energy absorption that uses a predetermined energy source outside and from within said predetermined Magnetic Field Generation with Particle Enhancement with Charge-based Absorption and
a said predetermined Magnetic Field Generation with Particle Enhancement with Charge-based Absorption with a plurality of part that produce said predetermined number of said predetermined charged particle of a predetermined polarity for creating a said predetermined charge-based magnetic/electrical field and
a said predetermined Magnetic Field Generation with Particle Enhancement with Charge-based Absorption that said predetermined characteristically interlace and said predetermined characteristically interact with another said predetermined magnetic/electrical charge-based field and
a said predetermined Magnetic Field Generation with Particle Enhancement with Charge-based Absorption that use said predetermined number of characteristic linear exchange for absorption of Particle Energy from the Particle Field and
a said predetermined Magnetic Field Generation with Particle Enhancement with Charge-based Absorption that use said predetermined number of characteristic non-linear exchange for absorption of Particle Energy from the Particle Energy Field and
a said predetermined Magnetic Field Generation with Particle Enhancement with Charge-based Absorption uses said characteristic interaction of a predetermined number of said predetermined charge-based magnetic/electrical energy field that said characteristically interacts within said Quantum Field within the Quantum Realm and
a said predetermined Magnetic Field Generation with Particle Enhancement with Charge-based Absorption uses characteristic predetermined interlacing of plurality of said predetermined charge-based magnetic/electrical energy field that predetermined characteristically interlaces within said Quantum Field within the Quantum Realm and
a said predetermined charge-based magnetic/electrical energy transfer that has said predetermined number of magnetic/electrical property for the transfer of said charge-based magnetic/electrical energy to a predetermined external system for use and
a said predetermined charge-based magnetic/electrical field that is formed by a said upper coil flowing and movement of predetermined charge-based magnetic/electrical field in a predetermined direction and
a said predetermined magnetic/electrical charge-based field that is formed by a said lower coil flowing and movement of predetermined charge-based magnetic/electrical field in a predetermined direction and
a said predetermined charge-based magnetic/electrical field move in a predetermined direction thereby creating a vortex of a predetermined strength, a predetermined concentration, a predetermined number of characteristic, a predetermined polarity, and a predetermined characteristic energy signature and
a said predetermined Magnetic Field Generation with Particle Enhancement with Charge-based Absorption that has said predetermined number of charged particle with a said predetermined charge characteristic, with predetermined polarity and with said predetermined number of chemical characteristic and
a said predetermined number of charge-based magnetic/electrical field which comprises of a said predetermined number of charge-based magnetic/electrical field characteristically interlacing with said predetermined number of charge-based magnetic/electrical field to form a predetermined Magnetic Field Generation with Particle Enhancement with Charge-based Absorption that accesses said Quantum Field within the Quantum Realm or Particle Field and
a said predetermined Magnetic Field Generation with Particle Enhancement with Charge-based Absorption that absorb a said predetermined charge-based magnetic/electrical energy from a said Quantum Field within the Quantum Realm or Particle Field, into a said predetermined characteristic interlacing said predetermined number of charge-based magnetic/electrical field and
a said predetermined Magnetic Field Generation with Particle Enhancement with Charge-based Absorption that predetermined transfer said predetermined charge-based magnetic/electrical energy from a said Quantum Field within the Quantum Realm or Particle Field, into a said predetermined characteristic interacting said predetermined charge-based magnetic/electrical field and
a said predetermined Magnetic Field Generation with Particle Enhancement with Charge-based Absorption that transfer a said predetermined charge-based magnetic/electrical energy from a said Quantum Field within the Quantum Realm or Particle Field, to said predetermined number of predetermined part that have said predetermined absorbefacient/conductive properties and
a said predetermined Magnetic Field Generation with Particle Enhancement with Charge-based Absorption that transfer said predetermined charge-based magnetic/electrical energy from said Quantum Field within the Quantum Realm or Particle Field, through said predetermined number of characteristic linear exchange and
a said predetermined Magnetic Field Generation with Particle Enhancement with Charge-based Absorption that absorb said predetermined charge-based magnetic/electrical energy from the said Quantum Field within the Quantum Realm or Particle Field, with said predetermined number of characteristic non-linear exchange and
a said predetermined Magnetic Field Generation with Particle Enhancement with Charge-based Absorption that absorb predetermined charge-based magnetic/electrical energy from the Quantum Field within the Quantum Realm or Particle Field, through predetermined charge-based magnetic/electrical predetermined alignment of number of ion into a predetermined number of vortex behavior within predetermined coil.

2. A said predetermined charge-based magnetic/electrical energy transfer of claim 1 wherein the said upper coil with said predetermined magnetic/electrical wire, which is preferably without any covering, with a predetermined shape, for example sinuous spiral, in the present invention, starting with a predetermined starting point with a predetermined opening of a predetermined size with a predetermined diameter on predetermined end of said coil, and following predetermined diameter with predetermined shape, after a predetermined length, there is placed a predetermined endpoint opposite a predetermined starting point on the other end of said coil with a predetermined sinuous spiral decreasing diameter.

3. A said predetermined charge-based magnetic/electrical energy transfer of claim 1 wherein the said lower coil with said predetermined magnetic/electrical wire, which is preferably without a covering, with a predetermined shape, for example sinuous spiral in the present invention, predetermined diameter and predetermined material, with a starting point on one end of lower coil, as desired by the user, with a predetermined opening of a predetermined diameter and after a predetermined length with predetermined diameter along a predetermined length of lower coil, there is placed, opposite of starting point, at the other end of said lower coil a predetermined opening with a predetermined decreasing diameter.

4. The said predetermined magnetic/electrical charge-based energy transfer of claim 1 wherein a said predetermined number of coil is made which can be induced to produce a said predetermined charge-based magnetic/electrical field and said predetermined charge-based magnetic/electrical field strength.

5. The said predetermined charge-based magnetic/electrical energy transfer of claim 1 wherein said predetermined number of space that surrounds a said predetermined Magnetic Field Generation with Particle Enhancement with Charge-based Absorption and has injected into the predetermined number of space surrounding predetermined coil, of a predetermined number of charged particle of a predetermined polarity, of a predetermined number of chemical properties, of a predetermined number of electrical properties, of a predetermined size, of a predetermined weight, of a predetermined number of particle per predetermined area.

6. The said predetermined charge-based magnetic/electrical energy transfer of claim 9 wherein said predetermined number of charged particle are injected by a means suitable to the user.

7. The said predetermined charge-based magnetic/electrical energy transfer of claim 1 wherein said predetermined Magnetic Field Generation with Particle Enhancement with Charge-based Absorption being of a said predetermined concentration of charged particles with a said predetermined polarity, with a said predetermined strength and with a said predetermined size of predetermined energy field.

8. The said predetermined charge-based magnetic/electrical energy transfer of claim 1 wherein a predetermined outside source supplies a said predetermined number of coil with a said predetermined charge-based magnetic/electrical energy and with a said predetermined polarity.

9. The said predetermined charge-based magnetic/electrical energy transfer of claim 1 wherein a said predetermined Magnetic Field Generation with Particle Enhancement with Charge-based Absorption is produced that has a said predetermined ab sorbefacient/conductive properties for a said predetermined energy transfer from a said magnetic/electrical charge-based energy state to another said magnetic/electrical charge-based energy state.

10. The said predetermined charge-based magnetic/electrical energy transfer of claim 1 wherein said predetermined Magnetic Field Generation with Particle Enhancement with Charge-based Absorption being of a said predetermined concentration of charged particles with a said predetermined polarity, with a said predetermined strength and with a said predetermined size of predetermined energy field.

11. The said predetermined charge-based magnetic/electrical energy absorption of claim 1 wherein a said predetermined casing surrounds a said predetermined number of charge-based magnetic/electrical coil, a said predetermined concentration of charged particle and a said predetermined number of space, which contains a said predetermined Magnetic Field Generation with Particle Enhancement with Charge-based Absorption for said predetermined absorbefacient/conductive charge-based magnetic/electrical energy transfer.

12. The said predetermined charge-based magnetic/electrical energy transfer of claim 1 wherein a said predetermined magnetic/electrical charge-based energy state which then concentrates said ions of said predetermined polarity, a predetermined number of charge characteristic and a predetermined number of chemical characteristics of a said predetermined concentration of charged particle.

13. The said predetermined charge-based magnetic/electrical energy absorption of claim 1 wherein a said plurality of predetermined space and a predetermined number of magnetic/electrical charge-based coil which converges said predetermined number of magnetic/electrical charge-based field to a said predetermined input magnetic/electrical charge-based energy state.

14. The said predetermined magnetic/electrical charge-based energy of claim 1 wherein said predetermined outside source supply with predetermined amount of said predetermined charge-based energy to a said predetermined number of predetermined coil.

15. The said predetermined magnetic/electrical charge-based energy absorption of claim 1 wherein with said predetermined outside source that supply with predetermined amount of said predetermined magnetic/electrical charge-based energy to said predetermined concentration of charged particle injected into said predetermined number of space.

16. The predetermined charge-based magnetic/electrical absorption of claim 1 where said predetermined Magnetic Field Generation with Particle Enhancement with Charge-based Absorption being within said predetermined number of space with predetermined number of charge-based energy field flow within predetermined number of space in said predetermined direction.

17. The said predetermined energy transfer of claim 1 wherein said predetermined Magnetic Field Generation with Particle Enhancement with Charge-based Absorption has said predetermined number of absorbefacient/conductive property.

18. The said predetermined Magnetic Field Generation with Particle Enhancement with Charge-based Absorption of claim 17 can be placed side by side to create a system for greater charge-based magnetic/electrical energy absorption and acquisition of Particle Energy from the Particle Field.

19. The said predetermined charge-based magnetic/electrical energy transfer unit of claim 17 can be placed side by side to create a predetermined system for predetermined greater energy absorption and predetermined acquisition of Quantum Energy from the Quantum Field within the Quantum Realm.

20. The said predetermined charge-based magnetic/electrical energy absorption in claim 1 wherein said predetermined charge-based magnetic/electrical energy flows with a said predetermined polarity in a said predetermined direction within a said conductive wire that has a said predetermined size, with a said predetermined shape and with a said predetermined composition and has predetermined absorbefacient/conductive properties.

21. The said predetermined charge-based magnetic/electrical absorption in claim 1 wherein a predetermined number of predetermined space allows for said characteristic interlacing of said predetermined number of charge-based magnetic/electrical energy field.

22. The said predetermined charge-based magnetic/electrical absorption in claim 1 wherein a predetermined number of predetermined space allows for said characteristic interacting of said predetermined number of charge-based magnetic/electrical energy field.

23. The said predetermined charge-based magnetic/electrical absorption in claim 1 wherein said predetermined wave formation, predetermined absorption, and predetermined energy transfer to a said predetermined containment system for use by the user.

24. The said predetermined charge-based magnetic/electrical energy absorption in claim 23 wherein a said predetermined wave formation moves in a predetermined direction.

25. The said predetermined charge-based magnetic/electrical energy transfer in claim 1 wherein a said predetermined number of waveform flow in a predetermined direction within said Particle Energy within the Particle Field.

26. The said predetermined charge-based magnetic/electrical energy transfer in claim 1 wherein a said predetermined number of charge-based magnetic/electrical field energy flow in a predetermined direction within a said Magnetic Field Generation with Particle Enhancement with Charge-based Absorption.

27. The said predetermined charge-based magnetic/electrical energy transfer in claim 1 wherein a said predetermined number of magnetic/electrical field energy flow in a predetermined direction within a said predetermined energy state.
